(19) United States
(12) Patent Application Publication
(10) Pub. No.: US 2018/0265953 A1
(43) Pub. Date: Sep. 20, 2018

(54) STAINLESS STEEL FOR COMPOUND THIN FILM SOLAR CELL SUBSTRATES, METHOD FOR PRODUCING SAME, AND COMPOUND THIN FILM SOLAR CELL

(71) Applicant: Solar Frontier K.K., Tokyo (JP)

(72) Inventors: Masaharu HATANO, Tokyo (JP); Akihito YAMAGISHI, Tokyo (JP); Toshihiko UCHIDA, Tokyo (JP); Akihiko ASANO, Tokyo (JP); Masahiro SAITOU, Tokyo (JP)

(73) Assignee: Solar Frontier K.K., Tokyo (JP)

(21) Appl. No.: 15/758,296

(22) PCT Filed: Sep. 1, 2016
(86) PCT No.: PCT/JP2016/075720

§ 371 Date: Mar. 7, 2018

(30) Foreign Application Priority Data
Sep. 8, 2015 (JP) 2015-176438

(51) Int. Cl. C22C 38/38; C22C 38/60; C23C 8/18; H01L 31/0392; H01L 31/0749

(52) U.S. Cl. CPC C22C 38/38; C22C 38/60; H01L 31/0749; H01L 31/0392; C23C 8/18

(57) ABSTRACT

The present invention addresses the problem of providing: a stainless steel which is provided with gas corrosion resistance suitable for substrates of compound thin film solar cells without requiring a surface treatment such as coating or plating; a method for producing this stainless steel; and a compound thin film solar cell which uses this stainless steel as a substrate. In order to solve the above-described problem, the present invention is characterized by forming an Fe—Cr—Al oxide film which has a film thickness of 15 nm or less and contains, in mass %, 0.03% or less of C, 2% or less of Si, 2% or less of Mn, 10-25% of Cr, 0.05% or less of P, 0.01% or less of S, 0.03% or less of N and 0.5-5% of Al, with the balance made up of Fe and unavoidable impurities, and wherein the maximum value of the Al concentration is 30% by mass or more and the Fe concentration at the depth of 2 nm from the surface is 30% or less in the profile of cation fractions excluding O and C ions. In addition, it is preferable that the surface film contains Si and Ti, while satisfying: Si is 0.3% or more; Ti is 0.03-0.5%; and (Mg+Ga) >0.001%. The surface film is obtained by carrying out annealing within the temperature range of 700-1,100° C. in a low-dew-point hydrogen gas.

### TECHNICAL FIELD

The present invention relates to the art of making a stainless steel substrate excellent in gas corrosion resistance without relying on surface treatment such as coating or plating and a method for producing the same. Further, the present invention relates to a compound thin film solar cell formed stacked with an inorganic insulating layer or CIS (Cu—In—Ga—Se—S) thin film or other compound light absorbing layer.

### BACKGROUND ART

In the past, for the material of the substrate of a compound thin film solar cell, ceramic or glass with a small coefficient of heat expansion has been used, but in addition to these, use of stainless steel with its excellent heat resistance is also being studied.

For example, PLTs 1 and 2 disclose insulating materials comprised of flat stainless steel sheets covered on their surfaces with aluminum or silicon oxide or silicon nitride films. These insulating materials are made using general-use ferritic stainless steel SUS430 (17 Cr steel). Further, PLT 3 discloses as stainless steel with a good film formability a material prescribing both the surface roughness parameters Rz and Rsk. For the stainless steel material, Nb- and Cu-containing SUS430J1L (18 Cr-0.4 Cu-0.4 Nb) and general use austenitic stainless steel SUS304 (18 Cr-8 Ni) are used.

In recent years, solar power has been growing into one of the main sources of energy for taking the place of fossil fuels. Technical development of solar cells has been accelerating. Among these as well, CIS thin films and other compound solar cells are considered promising in future as solar cells offering both low cost and high efficiency. A compound thin film solar cell, for example, is fabricated by forming an insulating layer on a substrate, forming a first electrode layer comprised of an Mo layer on the insulating layer, forming on that a light absorbing layer constituted by a film of a chalcopyrite-type compound layer, and further forming a second electrode layer. Here, the “chalcopyrite-type compound” is a five-element alloy such as a Cu—In—Ga—Se—S alloy (below, referred to as “CIS”).

In the past, for the solar cell substrate, glass, which is an insulator and has a small coefficient of heat expansion, had been widely used. However, glass is fragile and heavy, so mass production of a solar cell substrate of glass formed with a light absorbing layer on its surface has not been easy. Therefore, in recent years, for reducing weight and mass production, solar cell substrates made using stainless steel with its excellent balance of heat resistance and strength/ductility have also been developed.

For example, PLT 4 discloses a method for producing a solar cell substrate comprising forming an insulating film disclosed in PLT 1 or 2 on a 0.2 mm or less stainless steel foil and forming on that insulating substrate a back side electrode comprised of the Mo layer described in

and a light absorbing layer comprised of a Cu(In₁₋ₓGaₓ)Se2 film. For the material of the stainless steel foil, SUS430, SUS444 (18 Cr-2 Mo), and SUS447J1 (30 Cr-2 Mo) are being used.

Further, PLTs 5 and 6 disclose electrode substrates for CIS solar cell use comprised of Cu clad steel sheets having Cu cladding layers and formed with the above-mentioned Mo electrodes and light absorbing layers comprised of Cu(In₁₋ₓGaₓ)Se2 films on the Cu cladding layers. Here, as the material of the Cu clad steel sheet, use of ferritic stainless steel comprised of C: 0.0001 to 0.15%, Si: 0.001 to 1.2%, Mn: 0.001 to 1.2%, P: 0.001 to 0.04%, S: 0.0005 to 0.03%, Ni: 0 to 0.6%, Cr: 11.5 to 32.0%, Mo: 0 to 2.5%, Cu: 0 to 1.0%, Nb: 0 to 1.0%, Ti: 0 to 1.0%, Al: 0 to 0.2%, N: 0 to 0.025%, B: 0 to 0.01%, V: 0 to 0.5%, W: 0 to 0.3%, Ca, Mg, Y, REM (rare earth metals) in total of: 0 to 0.1%, and a balance of Fe and unavoidable impurities is disclosed. However, the ferritic stainless steel used in the examples is limited to SUS430.

Recently, PLT 7 has disclosed a stainless steel material formed with an insulating film with a good heat resistance and a method for producing the same. The base material stainless steel is comprised of C: 0.0001 to 0.15%, Si: 0.001 to 1.2%, Mn: 0.001 to 2.0%, P: 0.001 to 0.05%, S: 0.0005 to 0.03%, Ni: 0 to 2.0%, Cu: 0 to 1.0%, Cr: 11.0 to 32.0%, Mo: 0 to 3.0%, Al: 1.0 to 6.0%, Nb: 0 to 1.0%, Ti: 0 to 1.0%, N: 0 to 0.025%, B: 0 to 0.01%, V: 0 to 0.5%, W: 0 to 0.3%, Ca, Mg, Y, and REM (rare earth metals) in a total of: 0 to 0.1%, and a balance of Fe and unavoidable impurities and is formed with a mixed layer of a thickness of 1.0 μm or more comprised of NiO and NiFe₂O₄ through an Al oxide layer. Here, the mixed layer of NiO etc. and the Al oxide layer are made by coating Ni by electroplating, then heat treating it in the air to form the Al oxide layer at the interface of the steel and Ni plating and make the Ni plating change to an oxide layer.

PLTs 8 and 9 disclose a process for formation of a film in a compound thin film solar cell comprising forming the precursors Cu, In, and Ga of a light absorbing layer on a substrate by sputtering, then converting these to a CIS compound thin film by a heat treatment step of exposure to a hydrogen selenide (H₂Se), hydrogen sulfide (H₂S), or other highly corrosive gas atmosphere (selenization/sulfurization step). To use stainless steel for a substrate without relying on surface treatment such as coating and plating, securing gas corrosion resistance at the back surface of a device with an exposed metal surface has become an important issue.

### CITATION LIST

### Patent Literature

PLT 1: Japanese Patent Publication No. 6-299347A

### PLT 2: Japanese Patent Publication No. 6-306611A

### PLT 3: Japanese Patent Publication No. 2011-204723A

### PLT 4: Japanese Patent Publication No. 2012-169479A

### PLT 5: Japanese Patent Publication No. 2012-59854A

### PLT 6: Japanese Patent Publication No. 2012-59855A

### PLT 7: Japanese Patent Publication No. 2012-214886A

### PLT 8: Japanese Patent No. 3249407B

### PLT 9: Japanese Patent No. 3249408B

### SUMMARY OF INVENTION

### Technical Problem

As explained above, in aiming for lighter weight and mass production to promote the spread of solar cells, use of stainless steel for the substrate would be effective. To increase the spread of compound thin film solar cells as a major source of solar power generation in the future, durability to sustain the efficiency of conversion of the light absorbing layer at a high level plus reduction of cost through elimination of troublesome surface treatment of the stainless steel substrate such as coating are also important issues. This, however, as shown in PLTs 1 to 7, is limited to arts for application to coated, plated, or otherwise treated stainless steel. Therefore, an object of the present invention is to provide stainless steel provided with gas corrosion resistance suitable for a substrate of a compound thin film solar cell without relying on surface treatment such as coating or plating, a method for producing the same, and a compound thin film solar cell having that stainless steel as a base member.

### Solution to Problem

The inventors worked to solve the above problems by repeated intensive experiments and studies on surface oxide films of ferritic stainless steel with a coefficient of heat expansion close to that of glass and the resistance to gas corrosion which occurs in the process of production of a compound thin film solar cell and thereby completed the present invention. Below, the discoveries obtained by the present invention will be explained.

(a) Gas corrosion of a stainless steel substrate occurs due to the selenization by hydrogen selenide (H₂Se) and sulfurization by hydrogen sulfide (H₂S) performed in the film forming process at 400 to 600° C. Gas corrosion due to these occurs since the Fe component element of stainless steel reacts with the Se and S in the atmospheric gas to form compounds.

(b) The above-mentioned gas corrosion is greatly affected by the surface film formed on the material of the Al-containing ferritic stainless steel. Usually, the surface after pickling or polishing is formed with a thin Fe—Cr passivation film of several nm. Gas corrosion is easily promoted when a thin passivation film mainly comprised of Fe—Cr is formed on the surface. To improve the gas corrosion resistance of such a material, it is necessary to preoxidize the material etc. in a high temperature oxidizing atmosphere to form an oxide layer made of Al₂O₃ of over several tens of nm. A load is generated in the oxidizing process. Here, the new discovery was obtained that by raising the Al concentration in advance in the thin surface film of a stainless steel material and lowering the surfacemost Fe concentration, gas corrosion due to selenization and sulfurization in the gas environment can be remarkably suppressed.

(c) It was discovered that to raise the Al concentration in the surface film and lower the Fe concentration to suppress gas corrosion, rather than excessively raising the amount of addition of Al, addition of Si and Ti and addition of trace amounts of Mg or Ga are effective. These elements are all surface active elements and concentrate near the base iron interface to suppress surface concentration of Fe and have smaller free energy of formation of oxides compared with Cr, promote the selective oxidation of the easily oxidizing Al or Si and Ti, and contribute to the formation of a film having gas corrosion resistance. In particular, a remarkable effect is exhibited if making Si: 0.3% or more and Ti: 0.05% or more and the total content of Mg+Ga exceeds 0.001%.

(d) To raise the Al concentration in the surface film and efficiently lower the Fe concentration, bright annealing in a low dew point atmosphere containing hydrogen gas after cold working is effective. In this case as well, the above-mentioned addition of Si and Ti and addition of trace amounts of Mg and Ga are effective for forming a surface film.

(e) It was learned that a compound solar cell formed by using Al-containing ferritic stainless steel with the above-mentioned improved surface film as a substrate and performing selenization by hydrogen selenide (H₂Se) and sulfurization by hydrogen sulfide (H₂S) can be produced while suppressing gas corrosion and without impairing the cell performance

The gist of the present invention obtained based on the discoveries of the above (a) to (e) is as follows:

(1) Stainless steel for compound thin film solar cell substrates comprising stainless steel containing, by mass %, C: 0.03% or less, Si: 2% or less, Mn: 2% or less, Cr: 10 to 25%, P: 0.05% or less, S: 0.01% or less, N: 0.03% or less, and Al: 0.5 to 5% and having a balance of Fe and unavoidable impurities and having formed on its surface an Fe—Cr—Al oxide film with a thickness of 15 nm or less, with a profile of cation fractions other than O and C where a maximum value of Al concentration is 30 mass % or more, and with an Fe concentration at a depth of 2 nm from the surface of 30 mass % or less.

(2) The stainless steel for compound thin film solar cell substrates according to (1), further formed with an Fe—Cr—Al oxide film where in the cation fractions on the surface of the stainless steel, the maximum value of at least Si or Ti is 2 mass % or more.
(3) The stainless steel for compound thin film solar cell substrates according to (1) or (2), wherein the stainless steel contains, by mass %, one or more of Si: 0.3% or more, Ti: 0.03 to 0.5%, Mg: 0.05% or less, and Ga: 0.1% or less and satisfies Mg+Ga>0.001%.
(4) The stainless steel for compound thin film solar cell substrates according to any one of claims 1 to 3, wherein the stainless steel further contains, by mass %, one or more of Ni: 1% or less, Cu: 1% or less, Mo: 2% or less, V: 0.5% or less, Nb: 0.5% or less, Sn: 0.2% or less, Sb: 0.2%, W: 1% or less, Zr: 0.2% or less, Co: 0.2% or less, B: 0.005% or less, Ca: 0.005% or less, La: 0.1% or less, Y: 0.1% or less, Hf: 0.1% or less, and REM: 0.1% or less.
(5) A method for producing stainless steel for compound thin film solar cell substrates comprising heat treating stainless steel having a composition according to any one of (1), (3), and (4) in an atmosphere containing hydrogen gas at 700 to 1100° C. in temperature range so as to form an Fe—Cr—Al oxide film according to (1) or (2) on the surface of the stainless steel.
(6) A compound thin film solar cell having stainless steel according to any one of (1) to (4) as a substrate and having an insulating layer formed on the substrate, a first electrode layer formed on the insulating layer, a compound light absorbing layer formed on the first electrode layer, and a second electrode layer formed on the compound light absorbing layer.
Below, the inventions according to the steels of (1) to (6) will be referred to as “the present invention”.

### ADVANTAGEOUS EFFECTS OF INVENTION

According to the present invention, the remarkable effect is exhibited that it is possible to obtain stainless steel provided with a gas corrosion resistance suitable for a substrate of a compound thin film solar cell without relying on surface treatment such as coating and plating and obtain a compound thin film solar cell using the same as a substrate.

### BRIEF DESCRIPTION OF DRAWINGS

FIG. 1 is a graph showing the results of GDS analysis of the profiles of elements at the surface of stainless steel for substrate use.

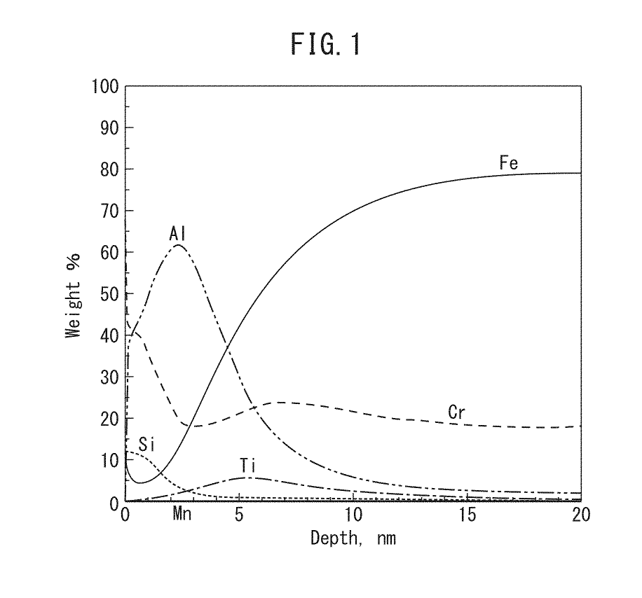

### DESCRIPTION OF EMBODIMENTS

Below, the requirements of the present invention will be explained in detail. Note that, the indications “%” in the contents of the elements mean “mass %” unless otherwise indicated.

(I) The reasons for limitation of the components will be explained below.

C forms a solid solution in a ferrite phase or forms Cr carbides to lower the oxidation resistance and obstruct the formation of the surface film targeted by the present invention. For this reason, the smaller the amount of C the better. The upper limit is made 0.03%. However, excessive reduction leads to a rise in the refining costs, so the lower limit is preferably made 0.001%. From the viewpoints of the oxidation resistance and manufacturability, the preferable range is 0.002 to 0.02%.

Si is an important element in securing the gas corrosion resistance targeted by the present invention. Si forms a solid solution in an oxide film and also concentrates at the oxide film/steel interface to improve the gas corrosion resistance in a hydrogen selenide (H₂Se) and hydrogen sulfide (H₂S) atmosphere. To obtain these effects, the lower limit is preferably made 0.1%. On the other hand, excessive addition invites a drop in the toughness and workability of steel, so the upper limit is made 2%. From the viewpoints of the gas corrosion resistance and basic properties, 1.5% or less is preferable. To positively utilize the effects of Si, 0.3% or more is preferable.

Mn suppresses the surface oxidation of Fe to promote the form of a surface film of Al or Si and Ti targeted by the present invention. To obtain these effects, the lower limit is preferably made 0.1% or more. On the other hand, excessive addition lowers the oxidation resistance and ends up obstructing the gas corrosion resistance targeted by the present invention, so the upper limit is made 2%. From the viewpoints of the oxidation resistance and the gas corrosion resistance of the present invention, 1% or less is preferable. To positively utilize the effects of Mn, 0.2 to 1% in range is preferable.

Cr is a component element providing the basis for not only corrosion resistance, but also formation of the surface film targeted by the present invention and securing gas corrosion resistance. In the present invention, if less than 10%, the targeted gas corrosion resistance is not sufficiently secured. Therefore, the lower limit is made 10%. However, excessive addition of Cr assists the formation of the brittle 6-phase when exposed to a high temperature atmosphere and invites a rise in the alloy cost. The upper limit is made 25% from the viewpoints of the basic properties and manufacturability and the gas corrosion resistance targeted by the present invention. From the viewpoints of the basic properties and gas corrosion resistance and the alloy cost, the preferable range is 13 to 22%, while the more preferable range is 16 to 19%.

P is an element obstructing the manufacturability and weldability. The smaller the content the better, so the upper limit is made 0.05%. However, excessive reduction leads to a rise in the refining costs, so the lower limit is preferably made 0.003%. From the viewpoint of the manufacturability and weldability, the preferable range is 0.005 to 0.04%, more preferably 0.01 to 0.03%.

S is an unavoidable impurity element contained in steel. It lowers the oxidation resistance and obstructs the gas corrosion resistance targeted by the present invention. In particular, the presence of Mn-based inclusions and solute S acts as the starting points of breakage of the surface oxide film when exposed to a high temperature atmosphere. Therefore, the lower the amount of S the better, so the upper limit is made 0.01%. However, excessive reduction leads to a rise in the costs of the materials and refining, so the lower limit is made 0.0001. From the viewpoints of the manufacturability and gas corrosion resistance, the preferable range is 0.0001 to 0.002%, while the more preferable range is 0.0002 to 0.001%.

N, like C, obstructs the gas corrosion resistance targeted by the present invention. For this reason, the smaller the amount of N, the better. The upper limit is made 0.03%. However, excessive reduction leads to a rise in the refining costs, so the lower limit is preferably made 0.002%. From the viewpoints of the gas corrosion resistance and manufacturability, the preferable range is 0.005 to 0.02%.

Al is not only a deoxidizing element, but is also an added element essential for achieving the gas corrosion resistance by improvement of the surface film targeted by the present invention. In the present invention, if less than 0.5%, the targeted film improvement and gas corrosion resistance cannot be obtained. Therefore, the lower limit is made 0.5%. However, excessive Al addition invites a drop in the toughness and weldability of the steel and obstructs productivity, so the alloy cost rises and problems arise in economicalness as well. The upper limit is made 5% from the viewpoints of the basic properties and economicalness. From the viewpoints of the gas corrosion resistance of the present invention and the basic properties and economicalness, the preferable range is 1.0 to 3.5%, while the more preferable range is 1.5 to 2.5%.

Ti not only improves the oxidation resistance through raising the purity of the steel via the action as a stabilizing element immobilizing the C and N, but also improves the gas corrosion resistance by improvement of the film targeted by the present invention. It is added in accordance with need to obtain these effects. In the case of addition, it is added in 0.03% or more where the effects are manifested. However, excessive addition leads to a rise in the alloy cost and a fall in the manufacturability along with the rise in the recrystallization temperature, so the upper limit is preferably made 0.5%. From the viewpoints of the alloy cost and the manufacturability and gas corrosion resistance, the preferable range is 0.05 to 0.35%, while the more preferable range for making positive use of the effect of Ti is 0.1 to 0.3%.

In addition to the above basic composition, to form the surface film targeted by the present invention and obtain gas corrosion resistance, one or both of Mg and Ga are preferably added. These elements, as explained above, concentrate near the base iron interface to suppress the surface concentration of Fe and as a result act to promote the selective oxidation of Al or Si and Ti. To obtain these effects, the lower limits of Mg and Ga are made 0.0005%. The total content of Mg and Ga is made over 0.001%. On the other hand, excessive addition raises the refining costs of the steel and obstructs the manufacturability, so the upper limits are made Mg: 0.05% and Ga: 0.1%. From the viewpoints of the gas corrosion resistance targeted by the present invention and the costs and manufacturability, Mg: 0.001 to 0.02% and Ga: 0.001 to 0.02% in range are preferable.

Further, the stainless steel of the present invention may further, in accordance with need, contain one or more of Ni: 1% or less, Cu: 1% or less, Mo: 2% or less, V: 0.5% or less, Nb: 0.5% or less, Sn: 0.2% or less, Sb: 0.2% or less, W: 1% or less, Zr: 0.5% or less, Co: 0.5% or less, B: 0.005% or less, Ca: 0.005% or less, La: 0.1% or less, Y: 0.1% or less, Hf: 0.1% or less, and REM: 0.1% or less.

Ni, Cu, Mo, V, Nb, W, Sn, Sb, and Co are elements effective for raising the high temperature strength and corrosion resistance of the stainless steel and are added in accordance with need. However, excessive addition leads to a rise in the alloy costs and obstruction of the manufacturability, so the upper limits of Ni, Cu, and W are made 1%. Mo is an element also effective for suppressing high temperature deformation due to a drop in the coefficient of heat expansion, so the upper limit is made 2%. The upper limits of V, Nb, Zr, and Co are made 0.5%. The upper limits of Sn and Sb are made 0.2% from the viewpoint of the manufacturability. In each element, the more preferable lower limit of the content is made 0.1%.

B and Ca are elements for raising the hot workability and secondary workability and are added in accordance with need. However, excessive addition leads to obstruction of manufacturability, so the upper limit is made 0.005%. The preferable lower limit is made 0.0001%.

Zr, La, Y, Hf, and REM improve the hot workability and cleanliness of the steel and are elements effective since the past for improvement of the oxidation resistance, so may be added as needed. However, the gas corrosion resistance targeted by the present invention does not rely on the effects of addition of these elements. When added, the upper limit of Zr is made 0.5%, while the upper limits of La, Y, Hf, and REM are respectively made 0.1%. The more preferable lower limit of Zr is made 0.01%, while the preferable lower limits of La, Y, Hf, and REM are made 0.001%. Here, “REM” means elements belonging to atomic numbers 57 to 71, for example, means Ce, Pr, Nd, etc.

In addition to the elements explained above, other elements may be included in a range not detracting from the effect of the present invention. The general impurity elements of the above-mentioned P and S first and foremost and Zn, Bi, Pb, Se, H, Ta, etc. are preferably reduced as much as possible. On the other hand, these elements may be controlled in ratio of content to be up to an extent where the object of the present invention is achieved. In accordance with need, one or more of Zn≤500 ppm, Bi100 ppm, Pb≤100 ppm, Se100 ppm, H≤100 ppm, and Ta≤500 ppm may be included.

(II) The reasons for limitation of the surface film will be explained below: The stainless steel for compound thin film solar cell substrates of the present invention is made one having the above-mentioned steel components and having a film in which Al and further Si and/or Ti are concentrated formed on its surface. The upper limit of the film thickness is made 15 nm. Considering productivity, bright annealing, or heat treatment or pickling giving an effect equal to bright annealing, is preferably performed to make the thickness 10 nm or less. The lower limit of the film thickness is not particularly prescribed, but preferably the thickness is made at least 2 nm where the effect on the gas corrosion resistance in H₂Se and H₂S is obtained. The more preferable range of film thickness is 3 to 8 nm.

In order for the above film composition to have an effect on the gas corrosion resistance in H₂Se and H₂S, in the profiles of cation fractions other than O and C, the maximum value of the Al concentration is made 30 mass % or more and the Fe concentration at a depth of 2 nm from the surface is made 30 mass % or less. Al concentrates from the inside layer of the surface film to the base iron interface and has the effect of remarkably suppressing the penetration of the Se or S of the corrosive gas to the steel. These effects are manifested by the Al concentration in the surface film being raised to a maximum value of 30 mass % or more, preferably 50 mass % or more, more preferably 60 mass % or more. The upper limit of the Al concentration is not particularly prescribed, but considering the efficiency of bright annealing etc. is made 90 mass %, more preferably 80 mass %. The Fe concentration falls by formation of a film with concentrated Al at the surface. It is therefore possible to reduce the corrosion products of compounds of Se and S with Fe. These effects appear by reducing the Fe concentration at a depth of 2 nm from the surface to 30 mass % or less, preferably 20 mass % or less, more preferably 10 mass % or less. The lower limit of Fe concentration is not particularly prescribed, but considering the efficiency of bright annealing etc., is 1 mass %, more preferably 3 mass %.

The surface film preferably further contains Si and/or Ti so as to enhance the gas corrosion resistance. If Si and Ti concentrate in the Fe—Cr—Al oxide film and at the film/base iron interface, the film has the action of suppressing the penetration of the Se and S of the corrosive gas into the steel and the formation of corrosion products. To obtain these effects, the concentrations of Si and Ti in the surface film are preferably raised to maximum values of 2 mass % or more. More preferably, the Si concentration is 10 mass % or more, while the Ti concentration is 5 mass % or more. The two elements are more preferably included compositely.

Regarding the presence of Fe, Cr, Al, Si, and Ti in the surface film, glow discharge optical emission spectrometry may be used to detect light elements such as O and C and the component elements Fe and Cr of steel and measure the profiles of the elements from the surface. From the results of measurement of the profiles of the elements from the surface, the film thickness can be found by the position where the intensity of detection of O becomes half in the depth direction from the surface (half width). The concentration of Fe down to 2 nm from the surface and the maximum values of Al, Si, and Ti can be found by removing the O and C and preparing profiles of elements converted to cation fractions.

(III) The method of production will be explained below: In steel of the components described in section (I), heat treatment under the following conditions is preferable for forming the surface film described in section (II). The material used includes sheets, foils, plates, and bars and wires. The method for producing the materials is not particularly prescribed. Here, “sheets” are defined as materials of thicknesses of 0.2 mm or more, “foils” as 0.02 to less than 0 2 mm, and “plates” as 6 mm or more. The surface roughness of the steel is not particularly prescribed and may JIS roughnesses of BA, 2B, 2D, No. 4, polished, etc.

The stainless steel of the present invention mainly covers cold rolled annealed sheet obtained by descaling hot rolled steel strip with annealing or without annealing, cold rolling it, then finish annealing it by bright annealing or if necessary descaling it. The finish annealing temperature is preferably made 700 to 1100° C. If less than 700° C., the softening and recrystallization of the steel become insufficient and sometimes the predetermined material properties cannot be obtained. On the other hand, if over 1100° C., the steel becomes coarse grained and the toughness and ductility of the steel are sometimes obstructed.

To form the surface film with concentrated Al and further Si and/or Ti targeted by the present invention, bright annealing in a low dew point atmosphere containing hydrogen gas after cold working is effective. The atmospheric gas in the bright annealing contains hydrogen gas in 50 vol % or more and a balance of an inert gas so as to suppress the oxidation of Fe and Cr and selectively cause Al and further Si and/or Ti to concentrate at the surface. The dew point of the atmospheric gas is preferably −40° C. or less. The hydrogen gas is preferably 80 vol % or more, more preferably 90 vol % or more. The inert gas of the balance is preferably the industrially inexpensive nitrogen gas, but may also be Ar gas or He gas. Further, it is also possible to mix oxygen or another gas into the atmospheric gas in a range of less than 5 vol % to an extent promoting or not obstructing the formation of the surface film targeted by the present invention. The temperature of the bright annealing is made the recrystallization temperature of the steel of 700° C. or more. To lower the dew point of the atmospheric gas, it is preferably made 800° C. or more, more preferably 850° C. or more. On the other hand, if over 1100° C., the steel becomes coarse grained and, as explained above, the steel falls in toughness and ductility etc. so this is not preferable in terms of the material properties. The heating temperature of the steel material is preferably made 850 to 1000° C. in range. The heating time at that temperature is preferably made within 10 minutes envisioning bright annealing on an industrial continuous annealing line. More preferably it is made within 5 minutes. When performing these bright annealing in a batch furnace, the lower limit of the heating temperature and the upper limit of the heating time are not particularly prescribed. For example, 700° C. and 24 hours are acceptable. Here, needless to say, the stainless steel of the present invention formed with the surface film targeted by the present invention and able to achieve gas corrosion resistance is not limited to the above bright annealing conditions.

(IV) The compound thin film solar cell will be explained below: The present invention provides a compound thin film solar cell using the stainless steel substrate described in section (I) and section (II). Below, a CIS compound thin film solar cell will be explained as an example, but the invention may also be applied to a compound thin film solar cell other than a CIS one. For example, as a compound thin film solar cell other than a CIS one, a CZTS one with a light absorbing layer comprised of a compound containing copper (Cu), zinc (Zn), tin (Sn), and a chalcogen element (selenium (Se) or sulfur (S)), a CdTe one with a light absorbing layer comprised of a compound containing cadmium (Cd) and tellurium (Te), etc. may be mentioned.

A CIS solar cell uses the stainless steel as a substrate and is formed on the device-forming surface with an insulating layer, first electrode layer, compound light absorbing layer, and second electrode layer. The insulating layer is preferably glass or low melting point glass having at least one of SiO₂, CaO, B₂O₃, SrO, BaO, Al₂O₃, ZnO, ZrO₂, MgO, Na₂O, and K₂O as components. The thickness of the insulating layer, considering the adhesion and flatness, is preferably 10 μm to 50 μm. The first electrode layer preferably uses Mo. From the viewpoint of the gas corrosion resistance in H₂Se and H₂S atmospheres, Ti, W, etc. may be used. The thickness of the electrode layer is preferably made tens of nm to several μm.

Next, the compound light absorbing layer is the part for converting striking sunlight etc. to electricity and can be formed by a CIS compound thin film comprised of Group IB-IIIB-VIB elements. The material of the CIS compound thin film may be made at least one type of compound semiconductor including at least one type of Group IB element selected from the group comprised of Cu and Ag, at least one type of Group IIIB element selected from the group comprised of Al, Ga, and In, and at least one type of Group VIB element selected from the group comprised of S and Se. As examples of specific compounds, copper indium diselenide (CuInSe₂), copper indium disulfide (CuInS₂), copper indium sulfur diselenide (Culn(SSe)₂), copper gallium diselenide (CuGaSe₂), copper gallium disulfide (CuGaS₂), copper indium gallium diselenide (Cu(InGa)Se₂), copper indium gallium disulfide (Cu(InGa)S₂), copper indium gallium sulfur diselenide (Cu(InGa)(SSe)₂), etc. may be mentioned, but to enhance the photoelectric conversion efficiency, in actuality, it should be mentioned that the component elements form profiles in the depth direction of the compound light absorbing layer and do not form a single compound layer. The thickness of these compound light absorbing layers, considering the efficiency of photoelectric conversion, is preferably several fractions of μm to tens of μm.

On a CIS compound light absorbing layer comprised of a P-type semiconductor, the chemical bath deposition method was used to form an extremely thin n-type high resistance ZnO buffer layer and form a pn heterojunction with the CIS compound light absorbing layer.

The second electrode layer is comprised of a transparent conductive film. For example, a zinc oxide thin film (ZnO), indium tin oxide (ITO), etc. doped with boron or aluminum or gallium to a high concentration can be used. The thickness of the electrode layer is preferably, for example, made 0.5 μm to 2.5 μm.

Note that the above-mentioned CIS solar cell thin film may also be made an integrated structure comprised of a plurality of cells connected in series.

### Example 1

Below, examples of the present invention will be explained.

Ferritic stainless steels having the components of Table 1 were smelted and hot rolled and annealed, then cold rolled to obtain thickness 0.05 to 0.5 mm foils or sheets. Here, the components of the steels were made the ranges prescribed by the present invention and ones other than them. The cold rolled steel sheets were all finish annealed by bright annealing (BA) in the range of 800 to 1000° C. where recrystallization is completed. The obtained steel sheets were analyzed for their surface films and were heat treated at 400 to 600° C. in H₂Se and H₂S for 0.5 to 1 hour in the film forming step of the CIS-based solar cells to evaluate the gas corrosion resistances. Further, steel sheets with good gas corrosion resistances were used to form CIS-based solar cells which were then measured for conversion efficiency.

TABLE 1
Components (mass %)

| Steel | C | Si | Mn | P | S | Cr | Al | N | Ti | Others |
|---|---|---|---|---|---|---|---|---|---|---|
| A | 0.028 | 1.80 | 0.15 | 0.030 | 0.0090 | 24.2 | 0.80 | 0.025 | — | |
| B | 0.008 | 0.35 | 0.25 | 0.019 | 0.0003 | 17.2 | 1.20 | 0.011 | 0.050 | |
| C | 0.011 | 1.10 | 0.30 | 0.025 | 0.0008 | 18.2 | 1.80 | 0.010 | 0.150 | Mg: 0.002, Ga: 0.001 |
| D | 0.006 | 0.45 | 0.21 | 0.019 | 0.0006 | 17.9 | 1.90 | 0.006 | 0.170 | Go: 0.0015, B: 0.0005, Sn: 0.01 |
| E | 0.003 | 1.10 | 0.30 | 0.038 | 0.0003 | 11.5 | 3.60 | 0.010 | — | Mo: 1.5, V: 0.15, La: 0.01, Ca: 0.005 |
| F | 0.005 | 0.90 | 1.80 | 0.027 | 0.0019 | 16.9 | 1.50 | 0.012 | 0.380 | Mg: 0.015, Y: 0.01, Zr: 0.01 |
| G | 0.015 | 0.55 | 0.35 | 0.025 | 0.0002 | 19.2 | 1.60 | 0.015 | 0.150 | Ni: 0.35, Cu: 0.45, Nb: 0.25, Mg: 0.001, Ga: 0.001 |
| H | 0.013 | 0.15 | 0.25 | 0.012 | 0.0005 | 18.1 | 3.10 | 0.015 | 0.170 | W: 0.1, Ga: 0.004, Mg: 0.0011 |
| I | 0.004 | 0.25 | 0.14 | 0.022 | 0.0007 | 10.6 | 0.90 | 0.010 | 0.110 | Mg: 0.001, Sn: 0.02 |
| J | 0.015 | 0.32 | 2.20 | 0.020 | 0.0007 | 16.3 | 1.20 | 0.016 | 0.150 | |
| K | 0.011 | 0.36 | 0.20 | 0.020 | 0.0105 | 16.2 | 1.10 | 0.015 | — | |
| L | 0.033 | 0.35 | 0.35 | 0.030 | 0.0007 | 13.2 | 0.90 | 0.031 | 0.090 | Ga: 0.002, Sn: 0.01 |
| M | 0.025 | 0.25 | 0.35 | 0.030 | 0.0007 | 25.4 | 0.55 | 0.025 | — | Nb: 0.25 |
| N | 0.012 | 0.38 | 0.32 | 0.021 | 0.0005 | 17.5 | 0.45 | 0.011 | 0.150 | |
| O | 0.009 | 0.42 | 0.25 | 0.019 | 0.0003 | 16.2 | 0.80 | 0.012 | 0.59 | |

The bright annealing was performed in an atmosphere containing hydrogen gas: 80 to 100 vol % and having a balance of nitrogen gas at 700 to 1050° C. with a dew point of atmospheric gas of −45 to −65° C. in range. The heating time was 1 to 3 minutes. For part, the annealing was performed in a batch furnace for 600 minutes. The surface films of the prepared steel sheets can be analyzed by GDS to measure the profiles of the detected elements from the surfaces and find the film thicknesses and compositions. As explained above, the film thickness is made the half value position of O. From the profiles of the elements converted to cation fractions, Fe is made the concentration at a depth of 2 nm from the surface and Al, Si, and Ti are the maximum values in the surface film. Before the heat treatment in H₂Se and H₂S, these test pieces were oxidized at 600 to 800° C. in dry air for 1 hour in the film forming step of the solar cells.

The gas corrosion resistance of the surfaces of the steel sheets was visually judged. A state with no corrosion observed was evaluated as “Very good”, light corrosion not leading to fall off of metal was evaluated as “Good”, and corrosion of an extent where metal fell off was evaluated as “Poor”. The gas corrosion resistance targeted by the present invention is the case corresponding to “Very good” to “Good”.

Table 2 shows together the surface films and results of evaluation of the gas corrosion resistance. Nos. 1 to 8 have components and surface films prescribed by the present invention and achieve suppression of corrosion in H₂Se and H₂S atmospheres of the process for formation of the CIS thin film solar cells. In particular, Nos. 3, 4, 6, 7, and 8 include trace elements Mg+Ga, satisfy the preferred Al concentration and Fe concentration in the surface films, and further contain Si and Ti in suitable ranges in the surface films. They exhibited remarkable gas corrosion resistance and were evaluated as “Very good”. Nos. 1, 2, and 5 had film compositions and gas corrosion resistance targeted by the present invention and were evaluated as “Good”. Steel Nos. 9 to 15 had steel components outside those prescribed in the present invention. Even if performing the bright annealing prescribed in the present invention, it was not possible to form surface films satisfying the conditions prescribed in the present invention and the gas corrosion resistance targeted by the present invention could not be obtained, so these were evaluated as “Poor”. CIS solar cells were fabricated using the above-mentioned “Good” to “Very good” stainless steel as substrates. Specifically, on a 945 mm×1239 mm size stainless steel substrate, 168 serial solar cells were prepared. The open area was about 1.12 m². The conversion efficiency as a cell property (based on open area) was over 13%. It was confirmed to be equal to or better than or no different compared to a glass substrate.

TABLE 2
Surface Films and Results of Evaluation of Gas Corrosion Resistance

| | | Sheet | Bright annealing | | | Surface film | | | | | | |
|---|---|---|---|---|---|---|---|---|---|---|---|---|
| | | thickness | H₂ | Temp. | Time | Thickness | | | | | Gas corrosion | |
| No. | Steel | mm | gas % | ° C. | min | nm | Al mass % | Fe mass % | Si mass % | Ti mass % | resistance | Remarks |
| 1 | A | 0.30 | 95 | 1050 | 3 | 7.0 | 35 | 20 | 15 | — | Good | Inv. ex. |
| 2 | B | 0.10 | 90 | 700 | 60 | 13.0 | 50 | 15 | 4 | 2 | Good | Inv. ex. |
| 3 | C | 0.15 | 95 | 920 | 1 | 5.0 | 65 | 5 | 12 | 5 | Very good | Inv. ex. |
| 4 | D | 0.30 | 90 | 920 | 1 | 4.0 | 75 | 5 | 5 | 10 | Very good | Inv. ex. |
| 5 | E | 0.50 | 85 | 880 | 2 | 4.0 | 60 | 25 | 5 | — | Good | Inv. ex. |
| 6 | F | 0.20 | 80 | 980 | 2 | 6.0 | 60 | 10 | 10 | 20 | Very good | Inv. ex. |
| 7 | G | 0.05 | 95 | 1020 | 1 | 5.0 | 65 | 5 | 10 | 5 | Very good | Inv. ex. |
| 8 | H | 0.35 | 80 | 970 | 1 | 3.0 | 75 | 5 | — | 15 | Very good | Inv. ex. |
| 9 | I | 0.45 | 80 | 850 | 2 | 6.0 | 25 | 40 | — | 3 | Poor | Comp. ex. |
| 10 | J | 0.40 | 80 | 920 | 2 | 7.0 | 25 | 35 | — | 2 | Poor | Comp. ex. |
| 11 | K | 0.35 | 80 | 930 | 1 | 5.0 | 40 | 35 | 2 | — | Poor | Comp. ex. |
| 12 | L | 0.50 | 80 | 920 | 3 | 7.0 | 25 | 40 | — | — | Poor | Comp. ex. |
| 13 | M | 0.15 | 80 | 980 | 2 | 3.0 | 25 | 10 | 2 | — | Poor | Comp. ex. |
| 14 | N | 0.25 | 90 | 930 | 1 | 5.0 | 20 | 10 | 5 | 5 | Poor | Comp. ex. |
| 15 | O | 0.35 | 80 | 970 | 2 | 7.0 | 25 | 15 | 2 | 55 | Poor | Comp. ex. |

(Note 1)
“—” means oxidation at 600° C. in the air not yet performed.
(Note 2)
Gas corrosion resistance: “Very good” means no corrosion, “Good” means slight corrosion (no metal falloff), and “Poor” means corrosion leading to metal falloff.
(Note 3)
Underlines mean film composition outside the present invention.

From the above results, in ferritic stainless steel, to impart a gas corrosion resistance suitable for a substrate of a compound thin film solar cell, it is necessary to make the surface film one where (i) the maximum value of the Al concentration is 30 mass or more and (ii) the Fe concentration at a depth of 2 nm from the surface is 30 mass % or less as prescribed in the present invention. Here, to raise the gas corrosion resistance, it is effective to raise the Al concentration to 60 mass % or more to reduce the Fe concentration to 10 mass % or less and form a surface film satisfying Si: 0.3% or more, Ti: 0.05 to 0.5%, and Mg+Ga>0.001% and having a maximum value of Si and/or Ti of 2 mass % or more. Furthermore, the surface film of the present invention can be produced by bright annealing. A compound thin film solar cell having this as a substrate gives cell properties equal to or better than those of a glass substrate or no different from those.

### INDUSTRIAL APPLICABILITY

According to the present invention, it is possible to obtain stainless steel having a surface film excellent in gas corrosive resistance suitable for compound thin film solar cell substrates and obtain a compound thin film solar cell using the same as a substrate even without relying on surface treatment such as coating and plating.

1. Stainless steel for compound thin film solar cell substrates comprising stainless steel containing, by mass %, C: 0.03% or less, Si: 2% or less, Mn: 2% or less, Cr: 10 to 25%, P: 0.05% or less, S: 0.01% or less, N: 0.03% or less, and Al: 0.5 to 5% and having a balance of Fe and unavoidable impurities and having formed on its surface an Fe—Cr—Al oxide film with a thickness of 15 nm or less, with a profile of cation fractions other than O and C where a maximum value of Al concentration is 30 mass % or more, and with an Fe concentration at a depth of 2 nm from the surface of 30 mass % or less.

2. The stainless steel for compound thin film solar cell substrates according to claim 1, wherein the Fe—Cr—Al oxide film includes cation fractions containing 2 mass % or more of at least Si or Ti.

3. The stainless steel for compound thin film solar cell substrates according to claim 1, wherein said stainless steel contains, by mass %, one or more of Si: 0.3% or more, Ti: 0.03 to 0.5%, Mg: 0.05% or less, and Ga: 0.1% or less and satisfies Mg+Ga>0.001%.

4. The stainless steel for compound thin film solar cell substrates according to claim 1, wherein said stainless steel further contains, by mass %, one or more of Ni: 1% or less, Cu: 1% or less, Mo: 2% or less, V: 0.5% or less, Nb: 0.5% or less, Sn: 0.2% or less, Sb: 0.2% or less, W: 1% or less, Zr: 0.2% or less, Co: 0.2% or less, B: 0.005% or less, Ca: 0.005% or less, La: 0.1% or less, Y: 0.1% or less, Hf: 0.1% or less, and REM: 0.1% or less.

5. The stainless steel of claim 1 produced by a method comprising heat treating said stainless steel in an atmosphere containing hydrogen gas at 700 to 1100° C. in a temperature range so as to form the Fe—Cr—Al oxide film on the surface of said stainless steel.

6. (canceled)

7. A compound thin film solar cell, comprising:
a substrate formed of a stainless steel comprising, by mass %, C: 0.03% or less, Si: 2% or less, Mn: 2% or less, Cr: 10 to 25%, P: 0.05% or less, S: 0.01% or less, N: 0.03% or less, and Al: 0.5 to 5% and having a balance of Fe and unavoidable impurities and having formed on its surface an Fe—Cr—Al oxide film with a thickness of 15 nm or less, with a profile of cation fractions other than O and C where a maximum value of Al concentration is 30 mass % or more, and with an Fe concentration at a depth of 2 nm from the surface of 30 mass % or less;
an insulating layer formed on said substrate;
a first electrode layer formed on said insulating layer;
a compound light absorbing layer formed on said first electrode layer; and
a second electrode layer formed on said compound light absorbing layer.
